(19) United States
(12) Patent Application Publication
(10) Pub. No.: US 2026/0282948 A1
(43) Pub. Date: Sep. 17, 2026

(54) FOUR-PIN TO-247 ENCAPSULATION STRUCTURE FOR POWER GALLIUM NITRIDE HEMT DEVICE

(71) Applicant: GANEXT (ZHUHAI) TECHNOLOGY CO., LTD., Zhuhai (CN)

(72) Inventors: Wenli ZHANG, Zhuhai (CN); Yifeng WU, Zhuhai (CN); Dajiang ZHANG, Zhuhai (CN)

(21) Appl. No.: 18/872,971

(22) PCT Filed: Jun. 8, 2023
(86) PCT No.: PCT/CN2023/099217

§ 371 Date: Dec. 9, 2024

(30) Foreign Application Priority Data
Jun. 9, 2022 (CN) 202210649449.5

(51) Int. Cl. H10W 70/40; H10W 74/10; H10W 90/00

(52) U.S. Cl. CPC H10W 70/461; H10W 70/481; H10W 74/129; H10W 90/756

(57) ABSTRACT

A four-pin TO-247 encapsulation structure for a power gallium nitride HEMT device includes: a conductive chip holder; a planar gallium nitride HEMT chip fixed on a surface of the conductive chip holder, where a gate, a source, and a drain are included on the front surface of the planar gallium nitride HEMT chip; and insertable pins disposed on the same side of the conductive chip holder.

This application claims priority to Chinese Patent Application No. 202210649449.5 filed with the China National Intellectual Property Administration (CNIPA) on Jun. 9, 2022, the disclosure of which is incorporated herein by reference in its entirety.

### TECHNICAL FIELD

The present application relates to the technical field of semiconductor device encapsulation, for example, a four-pin TO-247 encapsulation structure for a power gallium nitride HEMT device.

### BACKGROUND

TO-247 is an encapsulation structure widely used in power semiconductor devices such as insulated gate field-effect transistors (MOSFETs) and insulated gate bipolar transistors (IGBTs) and commonly has three pins and a drain contact. An insertable drain pin is connected to the area of a conductive chip holder so that the drain contact is formed. However, such a TO-247 encapsulation structure has very long insertable metal pins that generate excessive parasitic inductance. As a result, device stability and the efficiency of a power system are reduced during use. For silicon carbide MOSFET devices and/or gallium nitride high electron mobility transistor (HEMT) devices with high switching speeds and applications requiring high switching frequencies, the impact of a parasitic parameter caused by encapsulation largely restricts the performance of each of the semiconductor devices.

In the related art, to solve this problem, based on the common three-pin TO-247 encapsulation structure, one insertable Kelvin source pin is added so that a structure with four pins and a drain contact is formed, that is, a conductive chip holder is connected to an insertable drain pin. However, such a TO-247 encapsulation structure with the four pins and the drain contact is mainly applicable to a power semiconductor device with a vertical structure such as a silicon-based MOSFET or a silicon carbide MOSFET but cannot be adapted to a power semiconductor device with a planar structure such as a gallium nitride HEMT device. The main reason is that the drain of the power semiconductor device with the vertical structure is on the rear surface of a chip and can be directly interconnected to the conductive chip holder through a conductive connecting material and a lead frame while the rear surface of the gallium nitride HEMT chip needs to be electrically interconnected to a source on the front surface, so such an encapsulation structure with the four pins and the drain contact is not applicable to the gallium nitride HEMT chip.

### SUMMARY

The present application provides a four-pin TO-247 encapsulation structure for a power gallium nitride HEMT device to be applicable to the characteristics of a planar gallium nitride HEMT structure, where a source of a planar gallium nitride HEMT chip is electrically connected to a conductive chip holder and a corresponding pin, thereby improving the switching speed of the device, reducing switching losses, and enhancing the stability of a system.

The present application provides a four-pin TO-247 encapsulation structure for a power gallium nitride HEMT device. The encapsulation structure includes: a conductive chip holder; a planar gallium nitride HEMT chip fixed on a surface of the conductive chip holder, where a gate, a source, and a drain are included on the front surface of the planar gallium nitride HEMT chip; and insertable pins disposed on the same side of the conductive chip holder.

Optionally, the insertable pins include a drain pin, a source pin, a Kelvin source pin, and a gate pin that are sequentially arranged from left to right in a case where the front surface of the planar gallium nitride HEMT chip faces upwards.

Optionally, the encapsulation structure for the gallium nitride HEMT device further includes a first connecting member, where a first end of the first connecting member is connected to the source on the front surface of the planar gallium nitride HEMT chip, and a second end of the first connecting member is connected to the conductive chip holder.

Optionally, the insertable source pin is connected to the conductive chip holder, and the insertable Kelvin source pin is connected to the conductive chip holder.

Optionally, the insertable source pin is connected to the conductive chip holder, and the encapsulation structure for the gallium nitride HEMT device further includes a second connecting member, where a first end of the second connecting member is connected to the source on the front surface of the planar gallium nitride HEMT chip, a second end of the second connecting member is connected to the insertable Kelvin source pin, and the insertable Kelvin source pin and the conductive chip holder are spaced at a preset distance.

Optionally, the encapsulation structure for the gallium nitride HEMT device further includes a third connecting member, where a first end of the third connecting member is connected to the drain included on the front surface of the planar gallium nitride HEMT chip, a second end of the third connecting member is connected to an insertable drain pin, and the insertable drain pin and the conductive chip holder are spaced at a preset distance.

Optionally, the encapsulation structure for the gallium nitride HEMT device further includes a fourth connecting member, where a first end of the fourth connecting member is connected to the gate on the front surface of the planar gallium nitride HEMT chip, a second end of the fourth connecting member is connected to an insertable gate pin, and the insertable gate pin and the conductive chip holder are spaced at a preset distance.

Optionally, the encapsulation structure for the gallium nitride HEMT device further includes a conductive connecting layer, where the conductive connecting layer is disposed between the planar gallium nitride HEMT chip and the conductive chip holder and configured to fix the planar gallium nitride HEMT chip to the conductive chip holder.

Optionally, the conductive chip holder further includes a mounting hole located on the side of the conductive chip holder facing away from the insertable pins.

Optionally, the encapsulation structure further includes a case that seals and protects the planar gallium nitride HEMT chip, where the case covers the planar gallium nitride HEMT chip, the front surface of the conductive chip holder and side surfaces of the conductive chip holder, and the area where at the insertable pins, and the first connecting member, or the first connecting member and the second connecting member, or the third connecting member, or the fourth connecting member are connected.

Optionally, the sealing protective case of the encapsulation structure is made of an epoxy resin material or a metal material.

### BRIEF DESCRIPTION OF DRAWINGS

The drawings used in the description of embodiments are briefly described below.

FIG. 1 is a schematic diagram of a three-pin drain contact TO-247 encapsulation structure applicable to a vertical power semiconductor device according to the related art;

FIG. 2 is a schematic diagram of a four-pin drain contact TO-247 encapsulation structure applicable to a vertical power semiconductor device according to the related art;

FIG. 3 is a schematic diagram of a four-pin source contact TO-247 encapsulation structure applicable to a planar gallium nitride HEMT device according to an embodiment of the present application;

FIG. 4 is another schematic diagram of a four-pin source contact TO-247 encapsulation structure applicable to a planar gallium nitride HEMT device according to an embodiment of the present application;

FIG. 5 is a side view of a conductive connecting layer according to an embodiment of the present application; and

FIG. 6 is a schematic view of a sealing protective case according to an embodiment of the present application.

### DETAILED DESCRIPTION

For the understanding of solutions of the present application by those skilled in the art, the technical solutions in embodiments of the present application are described below in conjunction with the drawings in the embodiments of the present application. Apparently, the embodiments described below are only part of embodiments of the present application.

It is to be noted that terms such as “first” and “second” in the description, claims, and drawings of the present application are used to distinguish between similar objects and are not necessarily used to describe a particular order or sequence. It is to be understood that data used in this manner are interchangeable where appropriate so that the embodiments of the present application described herein can be implemented in an order not illustrated or described herein. Additionally, the terms “include” and “have” and any variations thereof are intended to encompass a non-exclusive inclusion. For example, a process, method, system, product, or device that includes a series of steps or units not only includes the expressly listed steps or units but may also include other steps or units that are not expressly listed or are inherent to such a process, method, product, or device.

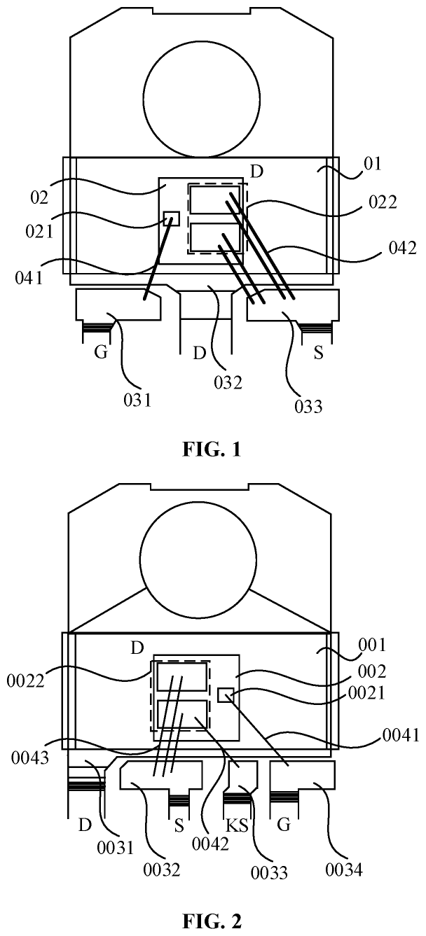

FIG. 1 is a schematic diagram of a conventional three-pin TO-247 encapsulation structure applicable to a vertical power semiconductor device according to the related art. As shown in FIG. 1, such an encapsulation structure mainly includes a conductive chip holder 01, a vertical power semiconductor chip 02, a gate 021 on the front surface of the vertical power semiconductor chip 02, a source 022 on the front surface of the vertical power semiconductor chip 02, a drain on the rear surface of the vertical power semiconductor chip 02, an insertable gate pin 031, an insertable drain pin 032, an insertable source pin 033, a first connecting member 041, and a second connecting member 042. The conductive chip holder 01 is connected to the insertable drain pin 032, and the drain on the rear surface of the vertical power semiconductor chip 02 is connected to the conductive chip holder 01 through a conductive connecting layer so that a drain contact structure is formed. A first end of the first connecting member 041 is connected to the gate 021 on the front surface of the vertical power semiconductor chip, and a second end of the first connecting member 041 is connected to the insertable gate pin 031. A first end of the second connecting member 042 is connected to the source 022 on the front surface of the vertical power semiconductor chip, and a second end of the second connecting member 042 is connected to the insertable source pin 033. The TO-247 encapsulation structure has very long insertable metal pins that generate excessive parasitic inductance during use. For power semiconductor devices with high switching speeds such as silicon carbide MOSFET devices and/or gallium nitride HEMT devices and applications requiring high switching frequencies, the impact of a parasitic parameter caused by the encapsulation structure largely restricts the performance of each of the semiconductor devices, increases driving difficulty, and reduces device stability. As a result, the efficiency of a power system is reduced. It is to be noted that the drain on the rear surface of the vertical power semiconductor chip 02 is disposed on the rear surface of the vertical power semiconductor chip 02 and therefore is not shown in FIG. 1.

FIG. 2 is a schematic diagram of a four-pin TO-247 encapsulation structure applicable to a vertical power semiconductor device according to the related art. As shown in FIG. 2, in the related art, based on the ordinary three-pin TO-247 encapsulation structure, an insertable Kelvin source pin is added so that a structure with four pins and a drain contact is formed. The encapsulation structure mainly includes a conductive chip holder 001, a vertical power semiconductor chip 002, a gate 0021 on the front surface of the vertical power semiconductor chip 002, a source 0022 on the front surface of the vertical power semiconductor chip 002, a drain of on the rear surface of the vertical power semiconductor chip 002, an insertable drain pin 0031, an insertable source pin 0032, an insertable Kelvin source pin 0033, an insertable gate pin 0034, a first connecting member 0041, a second connecting member 0042, and a third connecting member 0043. The conductive chip holder 001 is connected to the insertable drain pin 0031, and the drain on the rear surface of the vertical power semiconductor chip 002 is connected to the conductive chip holder 01 through a conductive connecting layer so that a drain contact structure is formed. A first end of the first connecting member 0041 is connected to the gate 0021 on the front surface of the vertical power semiconductor chip 002, and a second end of the first connecting member 0041 is connected to the insertable gate pin 0034. A first end of the second connecting member 0042 is connected to the source 0022 on the front surface of the vertical power semiconductor chip 002, and a second end of the second connecting member 0042 is connected to the insertable Kelvin source pin 0033. A first end of the third connecting member 0043 is connected to the source 0022 on the front surface of the vertical power semiconductor chip 002, and the second end of the second connecting member 0042 is connected to the insertable source pin 0032. The newly added pin can effectively decouple a drive loop from a power loop, enhancing the switching stability and reliability of the device. However, such a four-pin drain contact TO-247 encapsulation structure is not applicable to a gallium nitride HEMT chip with a planar structure. It is to be noted that the drain on the rear surface of the vertical power semiconductor chip 002 is disposed on the rear surface of the vertical power semiconductor chip 002 and therefore is not shown in FIG. 2.

Embodiments of the present application provide the technical solutions described below.

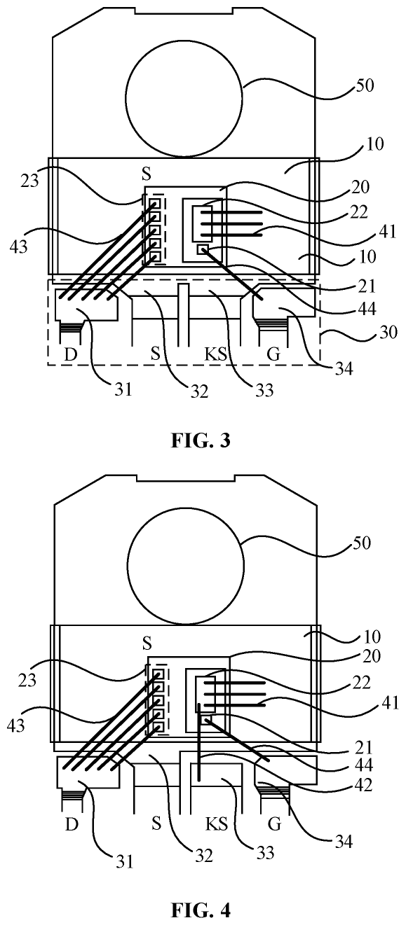

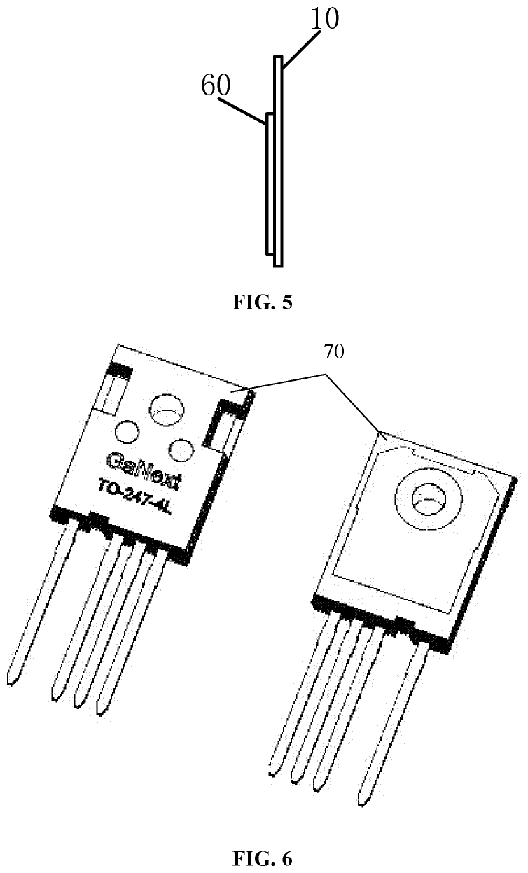

An embodiment of the present application provides a four-pin TO-247 encapsulation structure for a power gallium nitride HEMT device. FIG. 3 is a schematic diagram of a four-pin source contact TO-247 encapsulation structure applicable to a planar gallium nitride HEMT device according to an embodiment of the present application. As shown in FIG. 3, the encapsulation structure includes a conductive chip holder 10, a planar gallium nitride HEMT chip 20, and insertable pins 30. The planar gallium nitride HEMT chip 20 is fixed to a surface of the conductive chip holder 10 through a conductive connecting layer. A gate 21, a source 22, and a drain 23 are included on the front surface of the planar gallium nitride HEMT chip 20. The insertable pins 30 are disposed on the same side of the conductive chip holder 10.

The conductive chip holder 10 is configured to carry the planar gallium nitride HEMT chip 20 to be encapsulated. Compared with the vertical power semiconductor chip, the planar gallium nitride HEMT chip 20 is provided with the gate 21, the source 22, and the drain 23 that are all on the front surface of the chip. The insertable pins 30 are configured to perform corresponding electrical connection to the gate 21, the source 22, and the drain 23 that are disposed on the front surface of the planar gallium nitride HEMT chip 20. Thus, the gallium nitride HEMT chip implements an electrical function and operates normally. In the four-pin TO-247 encapsulation structure provided by this embodiment, all of the four insertable pins 30 are disposed on the same side of the conductive chip holder 10. Additionally, the sequence in which the electrical functions of the insertable pins are arranged is the same as the sequence in which the pin functions of a corresponding silicon-based MOSFET device or a corresponding silicon carbide-based MOSFET device with a vertical structure are arranged. Thus, the power gallium nitride HEMT device directly replaces the silicon-based MOSFET device or the silicon carbide-based MOSFET device with the vertical structure, thereby expanding the application range of the power gallium nitride HEMT device.

This embodiment provides the four-pin TO-247 encapsulation structure for the power gallium nitride HEMT device, where the source of the planar gallium nitride HEMT chip is electrically connected to the conductive chip holder and the corresponding pins. Thus, the characteristics of the planar gallium nitride HEMT device, for example, a high electron saturation velocity, high carrier mobility, and a high switching speed are fully used so that the switching stability of the device is enhanced, and the efficiency of a switch and the associated power system is improved. In addition, the sequence in which the electrical functions of the insertable pins of the planar gallium nitride HEMT encapsulation structure are arranged remains consistent with the positions where the electrical functions of insertable pins of a power semiconductor device with a vertical structure are arranged. With this embodiment, the planar gallium nitride HEMT device can directly replace the vertical silicon-based MOSFET device or the vertical silicon carbide MOSFET device. The provided insertable Kelvin source pin can effectively reduce the parasitic inductance so that the power loop is decoupled from a control loop, thereby reducing common-mode inductance. Thus, the switching speed of the gallium nitride HEMT device is increased, switching losses are reduced, and the reliability of the device and the stability of the power system in which the gallium nitride HEMT device is applied are enhanced.

Optionally, based on the preceding embodiment, with continued reference to FIG. 3, the insertable pins 30 include an insertable drain pin 31, an insertable source pin 32, an insertable Kelvin source pin 33, and an insertable gate pin 34 that are sequentially arranged from left to right on the same side of the conductive chip holder 10.

The manner in which the insertable pins 30 are arranged is the same as the manner in which the insertable drain pin D, the insertable source pin S, the insertable Kelvin source pin KS, and the insertable gate pin G of the four-pin TO-247 encapsulation structure applicable to the vertical power semiconductor device shown in FIG. 2 are arranged. Thus, complete compatibility is implemented. The insertable drain pin 31 is electrically connected to the drain 23 disposed on the front surface of the planar gallium nitride HEMT chip 20. The insertable source pin 32 and the insertable Kelvin source pin 33 are electrically connected to the source 22 disposed on the front surface of the planar gallium nitride HEMT chip 20. The insertable gate pin 34 is electrically connected to the gate 21 disposed on the front surface of the planar gallium nitride HEMT chip 20.

Optionally, with continued reference to FIG. 3, the four-pin source contact TO-247 encapsulation structure further includes a first connecting member 41. A first end of the first connecting member 41 is connected to the source 22 on the front surface of the planar gallium nitride HEMT chip 20, and a second end of the first connecting member 41 is connected to the conductive chip holder 10.

The first connecting member 41 is configured to electrically connect the source 22 on the front surface of the planar gallium nitride HEMT chip 20 to the conductive chip holder 10. The first connecting member 41 may be a metal wire, for example, an aluminum wire or a metal conductive strip, for example, a copper clip. The first end of the first connecting member 41 may be connected to the corresponding pad position of the source 22 on the front surface of the planar gallium nitride HEMT chip 20, and the second end of the first connecting member 41 may be connected to the corresponding bonding area on the conductive chip holder 10 through metal bonding or soldering.

Optionally, based on the preceding embodiment, with continued reference to FIG. 3, the insertable source pin 32 and the insertable Kelvin source pin 33 are each connected to the conductive chip holder 10.

The insertable source pin 32 and the insertable Kelvin source pin 33 of the four-pin source contact TO-247 encapsulation structure are each connected to the conductive chip holder 10. Therefore, the source 22 on the front surface of the planar gallium nitride HEMT chip 20 is directly connected to the conductive chip holder 10 through the first connecting member 41. That is, the source 22 is electrically interconnected to the insertable source pin 32 and the insertable Kelvin source pin 33 so that a conductive path is formed. Thus, the control loop formed between the insertable Kelvin source pin 33 and the insertable gate pin 34 is decoupled from the power loop formed between the insertable source pin 32 and the insertable drain pin 31, thereby increasing the switching speed of the encapsulated planar gallium nitride HEMT device, reducing the switching losses, and improving the stability of the system. This embodiment is an optional embodiment.

Optionally, FIG. 4 is another schematic diagram of a four-pin source contact TO-247 encapsulation structure applicable to the planar gallium nitride HEMT device according to an embodiment of the present application. This embodiment is a variation of each of the preceding multiple embodiments. As shown in FIG. 4, the insertable source pin 32 is connected to the conductive chip holder 10, and the four-pin source contact TO-247 encapsulation structure further includes a second connecting member 42. A first end of the second connecting member 42 is connected to the source 22 on the front surface of the planar gallium nitride HEMT chip 20, and a second end of the second connecting member 42 is connected to the insertable Kelvin source pin 33. The insertable Kelvin source pin 33 and the conductive chip holder 10 are spaced at a preset distance.

The first connecting member 41 electrically connects the corresponding pad of the source 22 on the front surface of the planar gallium nitride HEMT chip 20 to the contact area of the conductive chip holder 10 through metal bonding or soldering. The insertable source pin 32 is connected to the conductive chip holder 10. The insertable Kelvin source pin 33 is not connected to the conductive chip holder 10. Instead, the insertable Kelvin source pin 33 and the conductive chip holder 10 are spaced at the preset distance. The insertable Kelvin source pin 33 is connected to the source 22 on the front surface of the planar gallium nitride HEMT chip 20 through the second connecting member 42. Thus, the control loop formed by the insertable Kelvin source pin 33 and the insertable gate pin 34 can be further decoupled from the power loop formed by the insertable source pin 32 and the insertable drain pin 31, thereby further increasing the switching speed of the encapsulated planar gallium nitride HEMT device, reducing the switching losses, and improving the stability of the system. It is ensured that the insertable Kelvin source pin 33 and the conductive chip holder 10 are spaced at a certain preset distance. The preset distance may be set according to the requirements of an actual situation. The second connecting member 42 may also be a metal lead, for example, an aluminum wire or a metal conductive strip, for example, a copper clip. The second connecting member 42 is connected to the insertable Kelvin source pin 33 and the source 22 on the front surface of the planar gallium nitride HEMT chip 20 through metal bonding and/or soldering.

Optionally, based on the preceding embodiment, with continued reference to FIG. 4, the four-pin source contact TO-247 encapsulation structure further includes a third connecting member 43. A first end of the third connecting member 43 is connected to the drain 23 on the front surface of the planar gallium nitride HEMT chip 20, and a second end of the third connecting member 43 is connected to the insertable drain pin 31. The insertable drain pin 31 and the conductive chip holder 10 are spaced at a preset distance.

The insertable drain pin disposed at the leftmost end of one side of the conductive chip holder 10 and the conductive chip holder 10 are spaced at the preset distance so that the insertable drain pin 31 is spaced apart from both the insertable source pin 32 and the insertable Kelvin source pin 33. The third connecting member 43 may also be a metal lead, for example, an aluminum wire or a metal conductive strip, for example, a copper clip. The first end of the third connecting member 43 is connected to the corresponding pad position of the drain 23 on the front surface of the planar gallium nitride HEMT chip 20, and the second end of the third connecting member 43 is connected to the insertable drain pin 31 through metal bonding or soldering. Thus, the drain 23 on the front surface of the planar gallium nitride HEMT chip 20 is electrically connected to the insertable drain pin 31.

Optionally, with continued reference to FIG. 4, the four-pin source contact TO-247 encapsulation structure further includes a fourth connecting member 44. A first end of the fourth connecting member 44 is connected to the gate 21 on the front surface of the planar gallium nitride HEMT chip 20, and a second end of the fourth connecting member 44 is connected to the insertable gate pin 34. The insertable gate pin 34 and the conductive chip holder 10 are spaced at a preset distance.

The insertable gate pin 34 disposed at the rightmost end of the same side of the conductive chip holder 10 and the conductive chip holder 10 are spaced at the preset distance. The insertable gate pin 34 is electrically connected to the gate 21 on the front surface of the planar gallium nitride HEMT chip through the fourth connecting member 44. The fourth connecting member 44 may also be a metal lead, for example, an aluminum wire or a metal conductive strip, for example, a copper clip. The first end of the fourth connecting member 44 is connected to the corresponding pad position of the gate 21 on the front surface of the planar gallium nitride HEMT chip 20, and the second end of the fourth connecting member 44 is connected to the position of the insertable gate pin 34 through metal bonding or soldering. Thus, the gate 21 on the front surface of the planar gallium nitride HEMT chip 20 is electrically connected to the insertable gate pin 34.

Optionally, the four-pin source contact TO-247 encapsulation structure further includes the conductive connecting layer 60. The conductive connecting layer 60 is disposed between the planar gallium nitride HEMT chip 20 and the conductive chip holder 10.

The rear surface of the planar gallium nitride HEMT chip 20 is connected and fixed to the conductive chip holder 10 through the conductive connecting layer 60. The source 22 on the front surface of the planar gallium nitride HEMT chip 20 may be electrically continuous with the conductive chip holder 10 and the rear surface of the gallium nitride HEMT chip 20 directly through the conductive connecting layer 60 to implement electrical connection.

Optionally, based on the preceding multiple embodiments, with continued reference to FIG. 4, the conductive chip holder 10 further includes a mounting hole 50 located on the side of the conductive chip holder 10 facing away from the insertable pins 30.

The encapsulated device is fixed to a heatsink through the mounting hole 50. The mounting hole 50 is located on the side of the conductive chip holder 10 facing away from the insertable pins 30.

Optionally, the four-pin source contact TO-247 encapsulation structure further includes a sealing protective case 70. The sealing protective case 70 covers the planar gallium nitride HEMT chip 20, the front surface of the conductive chip holder 10, side surfaces of the conductive chip holder 10, and the area where the insertable pins 30, the first connecting member 41, the second connecting member 42, the third connecting member 43, and the fourth connecting member 44 are connected.

The sealing protective case 70 may be made of an epoxy resin material or a metal material to protect the planar gallium nitride HEMT chip 20, the first connecting member 41, the second connecting member 42, the third connecting member 43, the fourth connecting member 44, the insertable pins 30, and the conductive chip holder 10.

An implementation process for a processing technique of the four-pin source contact TO-247 encapsulation structure provided in this embodiment may include the following steps: scribing, chip loading, wire bonding, compression molding, post-curing, tin plating, trimming, and testing.

Using FIGS. 3 and 4 as examples, the steps of the processing technique of the four-pin source contact TO-247 encapsulation structure are described.

In S110, the conductive chip holder 10 and the insertable pins 30 are provided. The insertable pins 30 are disposed on the same side of the conductive chip holder 10. The conductive chip holder 10 and the insertable pins 30 are supported by the same lead frame.

Optionally, the insertable pins 30 include the insertable drain pin 31, the insertable source pin 32, the insertable Kelvin source pin 33, and the insertable gate pin 34 that are sequentially arranged.

Optionally, the conductive chip holder 10 further includes the mounting hole 50 located on the side of the conductive chip holder 10 facing away from the insertable pins 30.

In S120, the planar gallium nitride HEMT chip 20 is provided. The gate 21, the source 22, and the drain 23 are included on the front surface of the planar gallium nitride HEMT chip 20.

In the scribing step, the rear surface of a sample wafer is thinned and metallized. Then, laser grooving is performed down to the substrate of the wafer to scribe and cut the wafer. Thus, the sample wafer is cut into multiple gallium nitride HEMT chips 20 to be encapsulated. The gate, source, and drain of a planar gallium nitride chip 20 are all disposed on the front surface of the chip. Therefore, the planar gallium nitride chip 20 is classified as a planar power semiconductor.

In S130, the planar gallium nitride HEMT chip 20 is fixed on the surface of the conductive chip holder 10.

S130 corresponds to the chip loading step. In the chip loading step, the planar gallium nitride HEMT chip 20 to be encapsulated is fixed on the conductive chip holder 10 through soft solder, for example, high-lead solder. The planar gallium nitride HEMT chip 20 also remains fixed relative to the lead frame.

In the wire bonding step, electrode pads on the planar gallium nitride HEMT chip 20 may be connected to the conductive insertable pins 30 through aluminum wires or other metal materials with a connection technique. Thus, the planar gallium nitride HEMT chip 20 to be encapsulated is electrically connected to the conductive insertable pins 30. The wire bonding step is explained below.

Optionally, the conductive chip holder 10 formed in S110 has two structures. In a first structure shown in FIG. 3, the insertable source pin 32 is connected to the conductive chip holder 10, and the insertable Kelvin source pin 33 is connected to the conductive chip holder 10. For the four-pin source contact TO-247 encapsulation structure in FIG. 3, the following steps are further performed after the planar gallium nitride HEMT chip is fixed on the surface of the conductive chip holder 10 in S130.

In S140, the first end of the first connecting member 41 is connected to the corresponding pad position of the source 22 on the front surface of the planar gallium nitride HEMT chip 20, and the second end of the first connecting member 41 is connected to the corresponding contact area on the conductive chip holder 10 through metal bonding or soldering.

In S150, the third connecting member 43 is formed. The first end of the third connecting member 43 is connected to the corresponding pad position of the drain 23 on the front surface of the planar gallium nitride HEMT chip 20, and the second end of the third connecting member 43 is connected to the insertable drain pin 31. The insertable drain pin 31 and the conductive chip holder 10 are spaced at the preset distance.

In S160, the fourth connecting member 44 is formed. The first end of the fourth connecting member 44 is connected to the corresponding pad position of the gate 21 on the front surface of the planar gallium nitride HEMT chip 20, and the second end of the fourth connecting member 44 is connected to the insertable gate pin 34. The insertable gate pin 34 and the conductive chip holder 10 are spaced at the preset distance.

Optionally, the conductive chip holder 10 formed in S110 has the two structures. For a second structure shown in FIG. 4, the following steps are further performed after the planar gallium nitride HEMT chip is fixed on the surface of the conductive chip holder 10 in S130.

In S140, the first end of the first connecting member 41 is connected to the corresponding pad position of the source 22 on the front surface of the planar gallium nitride HEMT chip 20, and the second end of the first connecting member 41 is connected to the corresponding contact area on the conductive chip holder 10 through metal bonding or soldering.

In S150, the second connecting member 42 is formed. The first end of the second connecting member 42 is connected to the corresponding pad position of the source 22 on the front surface of the planar gallium nitride HEMT chip 20, and the second end of the second connecting member 42 is connected to the insertable Kelvin source pin 33. The insertable Kelvin source pin 33 and the conductive chip holder 10 are spaced at the preset distance.

In S160, the third connecting member 43 is formed. The first end of the third connecting member 43 is connected to the corresponding pad position of the drain 23 on the front surface of the planar gallium nitride HEMT chip 20, and the second end of the third connecting member 43 is connected to the insertable drain pin 31. The insertable drain pin 31 and the conductive chip holder 10 are spaced at the preset distance.

In S170, the fourth connecting member 44 is formed. The first end of the fourth connecting member 44 is connected to the corresponding pad position of the gate 21 on the front surface of the planar gallium nitride HEMT chip 20, and the second end of the fourth connecting member 44 is connected to the insertable gate pin 34. The insertable gate pin 34 and the conductive chip holder 10 are spaced at the preset distance.

After the wire bonding steps for the two four-pin source contact TO-247 encapsulation structures shown in FIG. 3 and FIG. 4 are completed, the protective case that seals and protects the gallium nitride HEMT device may be formed through a molding process. The protective case covers the planar gallium nitride HEMT chip 20, the first connecting member 41, the second connecting member 42, the third connecting member 43, the fourth connecting member 44, the insertable pins 30, and the conductive chip holder 10. In addition, the steps of post-curing, tin plating, trimming, and testing need to be performed. A metal case may be used as a sealing protective layer.

1. A four-pin TO-247 encapsulation structure for a power gallium nitride high electron mobility transistor (HEMT) device, comprising:
a conductive chip holder;
a planar gallium nitride HEMT chip fixed on a surface of the conductive chip holder, wherein a gate, a source, and a drain are disposed on a front surface of the planar gallium nitride HEMT chip; and
insertable pins disposed on a same side of the conductive chip holder.

2. The four-pin TO-247 encapsulation structure for the power gallium nitride HEMT device according to claim 1, wherein the insertable pins comprise an insertable drain pin, an insertable source pin, an insertable Kelvin source pin, and an insertable gate pin that are sequentially arranged from left to right in a case where the front surface of the planar gallium nitride HEMT chip faces upwards.

3. The four-pin TO-247 encapsulation structure for the power gallium nitride HEMT device according to claim 2, further comprising a first connecting member, wherein a first end of the first connecting member is connected to the source on the front surface of the planar gallium nitride HEMT chip, and a second end of the first connecting member is connected to the conductive chip holder.

4. The four-pin TO-247 encapsulation structure for the power gallium nitride HEMT device according to claim 3, wherein the insertable source pin is connected to the conductive chip holder, and the insertable Kelvin source pin is connected to the conductive chip holder.

5. The four-pin TO-247 encapsulation structure for the power gallium nitride HEMT device according to claim 3, wherein the insertable source pin is connected to the conductive chip holder; and
the four-pin TO-247 encapsulation structure for the gallium nitride HEMT device further comprises a second connecting member, wherein a first end of the second connecting member is connected to the source on the front surface of the planar gallium nitride HEMT chip, a second end of the second connecting member is connected to the insertable Kelvin source pin, and the insertable Kelvin source pin and the conductive chip holder are spaced at a preset distance.

6. The four-pin TO-247 encapsulation structure for the power gallium nitride HEMT device according to claim 1, further comprising a third connecting member, wherein a first end of the third connecting member is connected to the drain on the front surface of the planar gallium nitride HEMT chip, a second end of the third connecting member is connected to an insertable drain pin, and the insertable drain pin and the conductive chip holder are spaced at a preset distance.

7. The four-pin TO-247 encapsulation structure for the power gallium nitride HEMT device according to claim 1, further comprising a fourth connecting member, wherein a first end of the fourth connecting member is connected to the gate on the front surface of the planar gallium nitride HEMT chip, a second end of the fourth connecting member is connected to an insertable gate pin, and the insertable gate pin and the conductive chip holder are spaced at a preset distance.

8. The four-pin TO-247 encapsulation structure for the power gallium nitride HEMT device according to claim 1, further comprising a conductive connecting layer, wherein the conductive connecting layer is disposed between the planar gallium nitride HEMT chip and the conductive chip holder and configured to fix the planar gallium nitride HEMT chip to the conductive chip holder.

9. The four-pin TO-247 encapsulation structure for the power gallium nitride HEMT device according to claim 1, wherein the conductive chip holder further comprises a mounting hole located on a side of the conductive chip holder facing away from the insertable pins.

10. The four-pin TO-247 encapsulation structure for the power gallium nitride HEMT device according to claim 3, further comprising a sealing protective case that seals and protects the planar gallium nitride HEMT chip, wherein the sealing protective case covers the planar gallium nitride HEMT chip, the front surface of the conductive chip holder and side surfaces of the conductive chip holder, and an area where the insertable pins and the first connecting member are connected.

11. The four-pin TO-247 encapsulation structure for the power gallium nitride HEMT device according to claim 10, wherein the sealing protective case is made of an epoxy resin material or a metal material.

12. The four-pin TO-247 encapsulation structure for the power gallium nitride HEMT device according to claim 4, further comprising a sealing protective case that seals and protects the planar gallium nitride HEMT chip, wherein the sealing protective case covers the planar gallium nitride HEMT chip, the front surface of the conductive chip holder and side surfaces of the conductive chip holder, and an area where the insertable pins and the first connecting member are connected.

13. The four-pin TO-247 encapsulation structure for the power gallium nitride HEMT device according to claim 12, wherein the sealing protective case is made of an epoxy resin material or a metal material.

14. The four-pin TO-247 encapsulation structure for the power gallium nitride HEMT device according to claim 5, further comprising a sealing protective case that seals and protects the planar gallium nitride HEMT chip, wherein the sealing protective case covers the planar gallium nitride HEMT chip, the front surface of the conductive chip holder and side surfaces of the conductive chip holder, and an area where the insertable pins, the first connecting member and the second connecting member are connected.

15. The four-pin TO-247 encapsulation structure for the power gallium nitride HEMT device according to claim 14, wherein the sealing protective case is made of an epoxy resin material or a metal material.

16. The four-pin TO-247 encapsulation structure for the power gallium nitride HEMT device according to claim 6, further comprising a sealing protective case that seals and protects the planar gallium nitride HEMT chip, wherein the sealing protective case covers the planar gallium nitride HEMT chip, the front surface of the conductive chip holder and side surfaces of the conductive chip holder, and an area where the insertable pins and the third connecting member are connected.

17. The four-pin TO-247 encapsulation structure for the power gallium nitride HEMT device according to claim 16, wherein the sealing protective case is made of an epoxy resin material or a metal material.

18. The four-pin TO-247 encapsulation structure for the power gallium nitride HEMT device according to claim 7, further comprising a sealing protective case that seals and protects the planar gallium nitride HEMT chip, wherein the sealing protective case covers the planar gallium nitride HEMT chip, the front surface of the conductive chip holder and side surfaces of the conductive chip holder, and an area where the insertable pins and the fourth connecting member are connected.

19. The four-pin TO-247 encapsulation structure for the power gallium nitride HEMT device according to claim 18, wherein the sealing protective case is made of an epoxy resin material or a metal material.
